(19) United States
(12) Patent Application Publication
(10) Pub. No.: US 2026/0068525 A1
(43) Pub. Date: Mar. 5, 2026

(54) METHOD FOR MANUFACTURING THERMOELECTRIC MODULE

(71) Applicant: LINTEC Corporation, Tokyo (JP)

(72) Inventors: Kazuhiro KIKUCHI, Tokyo (JP); Haruki SUEYOSHI, Tokyo (JP); Mutsumi MASUMOTO, Beppu-shi (JP)

(21) Appl. No.: 19/378,985

(22) Filed: Nov. 4, 2025

Related U.S. Application Data
(63) Continuation of application No. PCT/JP2024/001291, filed on Jan. 18, 2024.

(51) Int. Cl. H10N 10/01

(52) U.S. Cl. CPC H10N 10/01

(57) ABSTRACT

A method includes preparing a first substrate including a first main surface and a second main surface and having a thermoelectric element bonded to the first main surface, dispensing a bonding material to a predetermined position on a third main surface of a second substrate including the third main surface and a fourth main surface, aligning the thermoelectric element and the bonding material with each other by disposing the first substrate on the second substrate placed with the fourth main surface in contact with a placement surface of a fixture such that the first main surface faces the second substrate, and bonding the first substrate and the second substrate via the thermoelectric element and the bonding material by bringing the thermoelectric element and the bonding material into contact with each other.

### CROSS-REFERENCE TO RELATED APPLICATION(S)

This application is a continuation of International Patent Application No. PCT/JP2024/001291 filed on Jan. 18, 2024, the entire disclosures of which is incorporated herein by reference.

### BACKGROUND OF THE INVENTION

### Field of the Invention

The present invention relates to a method for manufacturing a thermoelectric module.

### Description of the Related Art

A thermoelectric module using the Seebeck effect is known. Japanese Patent Laid-Open No. 2021-150608 discloses a technique in which an upper plate having a bonding material dispensed to a surface thereof is aligned on a lower plate bonded with a thermoelectric element, and the thermoelectric element and the bonding material are brought into contact with each other to integrate both plates. Japanese Patent Laid-Open No. 2021-150608 states that the upper plate dispensed with the bonding material is turned upside down to face the lower plate.

### SUMMARY OF THE INVENTION

In a process disclosed in Japanese Patent Laid-Open No. 2021-150608, after the bonding material is dispensed to the upper plate, a process of absorbing, lifting, and turning over the upper plate is required. In order to lift the upper plate by absorption, a space unusable as a thermoelectric module is required, for example, a space for absorption in which the bonding material is not dispensed to the upper plate is required.

An object of the present invention is to provide a technique advantageous in improving a manufacturing efficiency of a thermoelectric module.

In consideration of the above problem to be solved, a method for manufacturing a thermoelectric module according to an embodiment of the present invention includes: preparing a first substrate including a first main surface and a second main surface and having a thermoelectric element bonded to the first main surface; dispensing a bonding material to a predetermined position on a third main surface of a second substrate including the third main surface and a fourth main surface; aligning the thermoelectric element and the bonding material with each other by disposing the first substrate on the second substrate placed with the fourth main surface in contact with a placement surface of a fixture such that the first main surface faces the second substrate; and bonding the first substrate and the second substrate via the thermoelectric element and the bonding material by bringing the thermoelectric element and the bonding material into contact with each other.

According to the present invention, it is possible to provide a technique advantageous in improving a manufacturing efficiency of a thermoelectric module.

Further features of the present invention will become apparent from the following description of exemplary embodiments (with reference to the attached drawings).

### BRIEF DESCRIPTION OF THE DRAWINGS

FIG. 1 is a cross-sectional view illustrating a method for manufacturing a thermoelectric module according to the present embodiment.

FIG. 2 is a cross-sectional view illustrating a method for manufacturing a thermoelectric module according to the present embodiment.

FIG. 3 is a cross-sectional view illustrating a method for manufacturing a thermoelectric module according to the present embodiment.

FIG. 4 is a cross-sectional view illustrating a method for manufacturing a thermoelectric module according to the present embodiment.

### DESCRIPTION OF THE EMBODIMENTS

An embodiment will be described in detail below with reference to the accompanying drawings. It should be noted that the following embodiment does not limit the invention according to the claims, and all combinations of features described in the embodiment are not necessarily essential to the invention. Any two or more features among a plurality of features described in the embodiment may be combined. The same or similar components are denoted by the same reference numerals, and redundant description is omitted.

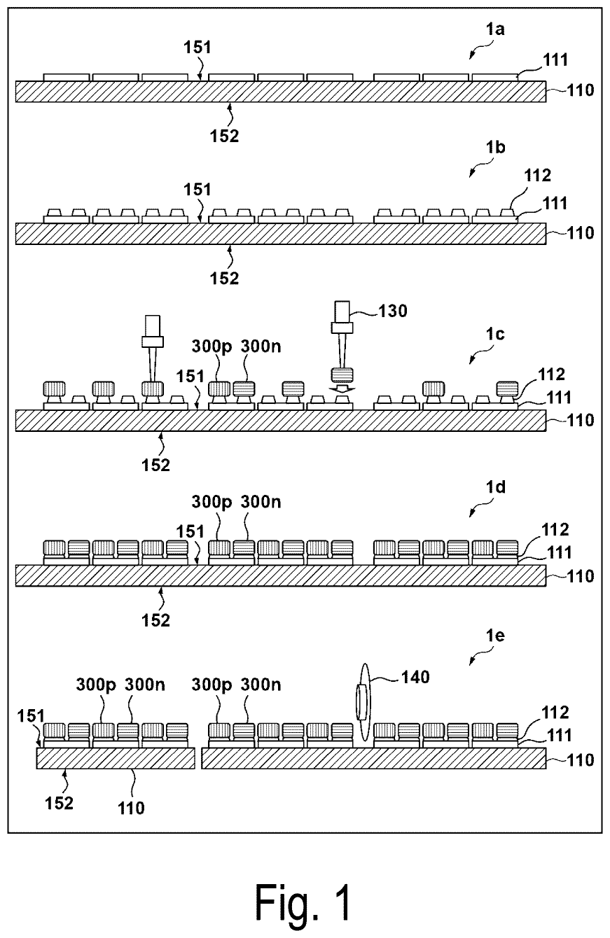

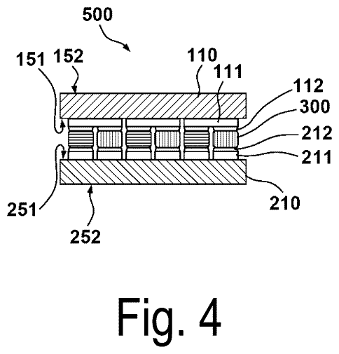

A method for manufacturing a thermoelectric module according to an embodiment of the present disclosure will be described below with reference to FIGS. 1 to 4. In a thermoelectric module 500 according to the present embodiment, as illustrated in FIG. 4, a plurality of thermoelectric elements 300 are arranged between a substrate 110 and a substrate 210.

The substrate 110 and the substrate 210 may be an insulating substrate. For example, a plastic film may be employed for the substrate 110 and the substrate 210. The plastic film may be a polyimide film, a polyamide film, a polyetherimide film, a polyaramid film, a polyamide-imide film, a glass epoxy sheet, or the like. The substrate 110 and the substrate 210 may be formed of the same material or different materials. A thickness of the substrate 110 and the substrate 210 may be 1 μm or greater and 1000 μm or less, for example, 10 μm or greater and 500 μm or less, or further, for example, 20 μm or greater and 100 μm or less. The material used for the substrate 110 and the substrate 210 is not limited to plastic. For example, ceramics such as alumina or aluminum nitride may be employed for the substrate 110 and the substrate 210. For example, an electrically conductive material covered with an insulating layer, such as an aluminum substrate having a surface formed with an alumina layer may be employed for the substrate 110 and the substrate 210.

In the thermoelectric module 500, the thermoelectric elements 300 may be disposed between the substrate 110 and the substrate 210 such that a p-type thermoelectric element 300p (for example, illustrated in 1c of FIG. 1) and an n-type thermoelectric element 300n (for example, illustrated in 1c of FIG. 1) are electrically connected in series. The thermoelectric element 300p and the thermoelectric element 300n are illustrated using hatchings different from each other as illustrated in 1c of FIG. 1 and the like. However, as illustrated in FIG. 4, the thermoelectric element 300p and the thermoelectric element 300n are not necessarily arranged alternately, and may be arranged in an appropriate order according to the configuration of electrode patterns 111 and 211 arranged on the substrate 110 and the substrate 210. Each of the thermoelectric elements 300 may be formed of various types of thermoelectric materials including bismuth-tellurium based, telluride based, antimony-tellurium based, zinc-antimony based, silicon-germanium based, bismuth selenide based, silicide based, oxide based, and sulfide based thermoelectric materials. A thickness of the thermoelectric element 300 in a direction sandwiched between the substrate 110 and the substrate 210 may be, for example, 10 μm or greater and 1000 μm or less, further, for example, 20 μm or greater and 500 μm or less, still further, for example, 50 μm or greater and 200 μm or less, or yet further 80 μm or greater and 120 μm or less. Now, the method for manufacturing the thermoelectric module 500 according to the present embodiment will be described. First, a step of preparing the substrate 110 including a main surface 151 and a main surface 152 and having the thermoelectric element 300 bonded to the main surface 151 as illustrated in 1e of FIG. 1 will be described. First, as illustrated in 1a of FIG. 1, the electrode pattern 111 is formed on the main surface 151 of the substrate 110. For example, a material including gold, copper, molybdenum, nickel, aluminum, rhodium, platinum, chromium, palladium, tungsten, or stainless steel, or an alloy thereof may be employed in the electrode pattern 111. In addition to the metal material, the electrode pattern 111 may be formed using a paste material containing a solvent or a resin component. When the paste material is used, the solvent, the resin component, or the like may be removed by firing or the like. For example, silver paste or aluminum paste may be employed for the paste material.

Examples of methods for forming the electrode pattern 111 include a method for processing the electrode pattern 111 into a predetermined pattern shape, for example, by a well-known physical treatment or chemical treatment based on photolithography or by using such treatments in combination, or a method for forming a pattern of the electrode through screen printing, stencil printing, inkjet printing, or the like. Examples of methods for forming an electrode not formed with a pattern include vacuum film formation methods including a physical vapor deposition (PVD) method such as a vacuum vapor deposition method, a sputtering method, and an ion plating method, or a chemical vapor deposition (CVD) method such as thermal CVD and atomic layer deposition (ALD), or a wet process such as various types of coating methods including a dip coating method, a spin coating method, a spray coating method, a gravure coating method, a die coating method, or a doctor blade method, and an electrodeposition method, as well as a silver salt method, an electrolytic plating method, an electroless plating method, and lamination of metal foils. Such methods are appropriately selected according to the metal material. When ceramics such as alumina or aluminum nitride is employed for the substrate 110, the electrode pattern 111 may be formed by using a DBC method, an AMB method, or the like.

The electrode pattern 111 is required to have high electrical conductivity. High electrical conductivity can be easily achieved in electrodes in which a film is formed by a plating method or a vacuum film formation method, and thus, the electrode pattern 111 may be formed by using vacuum film formation methods such as a vacuum vapor deposition method and a sputtering method, an electrolytic plating method, and an electroless plating method. The electrode pattern 111 can be easily formed through a hard mask such as a metal mask depending on the dimensions of the electrode pattern 111 to be formed and the required dimensional accuracy. Furthermore, when a film is formed by a vacuum film formation method, in order to, for example, improve adhesion with the substrate 110 to be used and remove moisture, the film may be formed while heating the substrate 110 to be used as long as the heating does not impair the characteristics of the substrate 110. In a case of forming a film using a plating method, a film may be further formed by an electrolytic plating method on a film formed by an electroless plating method.

A thickness of the electrode pattern 111 may be, for example, 10 nm or greater and 200 μm or less, further, for example, 30 nm or greater and 150 μm or less, or, still further, for example, 50 nm or greater and 120 μm or less. A thickness of the electrode pattern 111 may be appropriately set in accordance with a resistance value and the like required for the electrode pattern 111. The above-described material and configuration can also be used for the electrode pattern 211 provided on a main surface 251 of the substrate 210 described later.

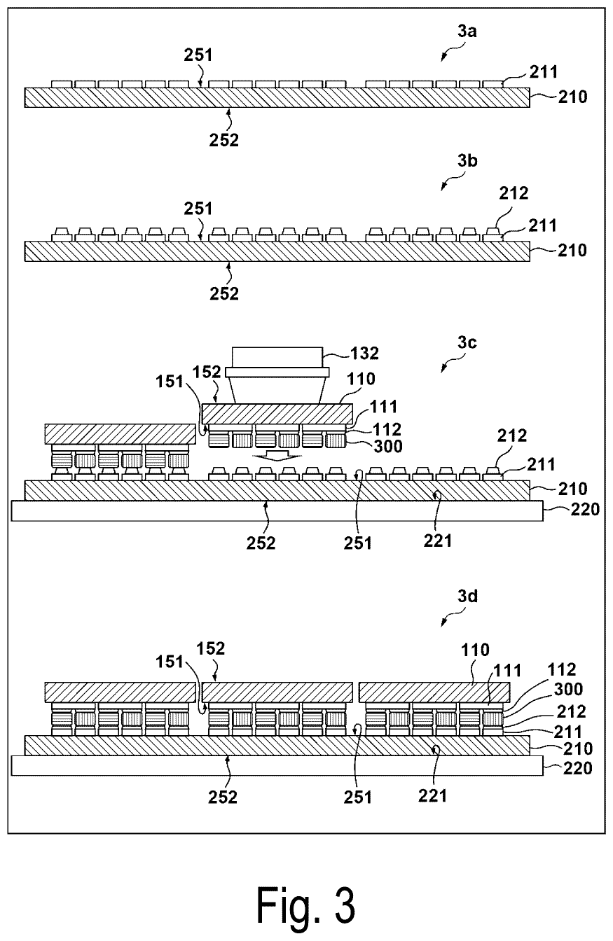

Next, as illustrated in 1b of FIG. 1, for example, cream solder is printed on the electrode pattern 111 as a bonding material 112 for bonding the thermoelectric element 300. The cream solder can be dispensed onto the electrode pattern 111 with high accuracy and in a short time by, for example, screen printing using a stencil plate. Examples of the solder material include known materials such as Sn, Sn/Pb alloys, Sn/Ag alloys, Sn/Cu alloys, Sn/Ag/Cu alloys, Sn/Sb alloys, Sn/In alloys, Sn/Zn alloys, Sn/In/Bi alloys, Sn/In/Bi/Zn alloys, Sn/Bi/Pb/Cd alloys, Sn/Bi/Pb alloys, Sn/Bi/Cd alloys, Bi/Pb alloys, Sn/Bi/Zn alloys, Sn/Bi alloys, Sn/Bi/Pb alloys, Sn/Pb/Cd alloys, and Sn/Cd alloys. A thickness of the bonding material 112 may be, for example, 10 μm or greater and 200 μm or less, further, for example, 20 μm or greater and 150 μm or less, still further, for example, 30 μm or greater and 130 μm or less, or, yet further, 40 μm or greater and 120 μm or less after a reflow step described later. A thickness at which a number of bonds between the electrode pattern 111 and the thermoelectric element 300 are stably formed may be appropriately selected. The above-described material and configuration can also be used for a bonding material 212 disposed on the electrode pattern 211 provided on the substrate 210 described later. However, if both the bonding material 112 and the bonding material 212 are melted at the same time in a step of heating the bonding material 212 illustrated in 3d of FIG. 3 described later, misalignment may occur, and the mounting position may be unstable. Therefore, the materials and the configurations of the bonding material 112 and the bonding material 212 may be selected such that the melting temperature of the bonding material 112 is higher than the melting temperature of the bonding material 212.

After cream solder is disposed on the electrode pattern 111 as the bonding material 112, the thermoelectric element 300 (the p-type thermoelectric element 300p and the n-type thermoelectric element 300n) is disposed on the bonding material 112 as illustrated in 1c of FIG. 1. For example, the thermoelectric element 300 may be disposed on the bonding material 112 by using the support 130. The support 130 can be, for example, a support for surface-mounting such as a flip-chip bonder. As illustrated in 1d of FIG. 1, the thermoelectric element 300 is bonded to the electrode pattern 111 arranged on the substrate 110 via the bonding material 112 by performing a heating process using a reflow oven or the like after the thermoelectric element 300 is arranged at a predetermined position on the electrode pattern 111 via the bonding material 112. By using the reflow step, the plurality of the thermoelectric elements 300 can be disposed on the electrode pattern 111 of the substrate 110 with high density and high accuracy. That is, the smaller thermoelectric elements 300 can be disposed at narrower intervals on the electrode pattern 111. For example, when the surface of the thermoelectric element 300 in contact with the electrode pattern 111 is rectangular, a length of one side of the electrode pattern 111 may be, for example, 0.01 mm or greater and 10 mm or less, further, for example, 0.1 mm or greater and 2 mm or less, or still further, for example, 0.2 mm or greater and 0.8 mm or less. An interval at which the thermoelectric elements 300 are arranged may be, for example, 0.01 mm or greater and 5 mm or less, further, for example, 0.04 mm or greater and 1 mm or less, or, still further, for example, 0.08 mm or greater and 0.20 mm or less.

Although not illustrated in 1c of FIG. 1 or the like, a solder receiving layer may be disposed between the bonding material 112 and the thermoelectric element 300. Further, a solder receiving layer may also be disposed between the bonding material 212 and the thermoelectric element 300, which will be described later. The solder receiving layer has a function of improving a bonding performance between the thermoelectric element 300 and the bonding material 112 (the bonding material 212), and is directly bonded to the thermoelectric element 300. The solder receiving layer may include a metallic material. The metal material may be at least one type selected from gold, silver, nickel, aluminum, rhodium, platinum, chromium, palladium, tin, and alloys containing any one of such metal materials. Among such metal materials, the metal material may be gold, silver, nickel, aluminum, or a two-layer structure of tin and gold. From the viewpoints of material cost, high thermal conductivity, and bonding stability, silver, nickel, and aluminum are more suitable as the solder receiving layer.

A thickness of the solder receiving layer may be, for example, 10 nm or greater and 50 μm or less, further, for example, 50 nm or greater and 16 μm or less, still further, for example, 200 nm or greater and 4 μm or less, or, yet further, 500 nm or greater and 3 μm or less. When the thickness of the solder receiving layer is in such a range, adhesion with the surface of the thermoelectric element 300 and adhesion with the bonding material 112 (bonding material 212) are excellent, and a bonding with high reliability can be obtained. In addition, not only electrical conductivity but also thermal conductivity can be maintained at a high level, and thus, as a result, the thermoelectric performance as the thermoelectric module 500 is not deteriorated and is maintained. The solder receiving layer may be used as a single layer by depositing a metal material as it is, or may be used as a multilayer by laminating two or more metal materials.

The solder receiving layer may be formed using the above-described metal materials. From the perspective of maintaining thermoelectric performance, the solder receiving layer is required to exhibit high electrical conductivity and high thermal conductivity. Therefore, a film of the solder receiving layer may be formed by using the above-described electrolytic plating method, electroless plating method, or vacuum film formation method.

The substrate 110 having the main surface 151 bonded with the thermoelectric element 300 may be prepared through the steps described above. For example, after the thermoelectric element 300 is bonded to the substrate 110, as illustrated in 1e of FIG. 1, the substrate 110 bonded with the thermoelectric element 300 may be singulated into units each having a predetermined configuration (for example, a predetermined number of the thermoelectric elements 300). The substrate 110 may be singulated using an appropriate means such as dicing. In the configuration illustrated in 1e of FIG. 1, a dicing blade 140 for dicing is described in an example. Hereinafter, even when the substrate 110 is singulated, a unit including the singulated substrate 110 may be simply referred to as “the substrate 110” or “the substrate 110 having the main surface 151 bonded with the thermoelectric element 300”.

The substrate 210 of the substrates 110 and 210 included in the thermoelectric module 500 is illustrated in 3a of FIG. 3. The substrate 210 includes a main surface 251 and a main surface 252. An electrode pattern 211 is formed on the main surface 251 of the substrate 210. For the electrode pattern 211, the same material as that of the electrode pattern 111 provided on the main surface 151 of the substrate 110 may be used, or a different material may be used. A thickness of the electrode pattern 211 may be the same as or different from that of the electrode pattern 111.

Next, as illustrated in 3b of FIG. 3, the bonding material 212 is disposed at a predetermined position on the main surface 251 of the substrate 210. The predetermined position may be on the electrode pattern 211 disposed on the main surface 251 of the substrate 210. For example, cream solder is employed for the bonding material 212 similarly to the bonding material 112. The cream solder can be dispensed onto the electrode pattern 211 with high accuracy and in a short time by, for example, screen printing using a stencil plate. A step of preparing the substrate 210 including the electrode pattern 211 illustrated in 3a of FIG. 3 and a step illustrated in 3b of FIG. 3 may be performed in parallel with the step of preparing the substrate 110 having the main surface 151 bonded with the thermoelectric element 300 illustrated in 1a to 1e of FIG. 1, for example. For example, the steps illustrated in 3a and 3b of FIG. 3 may be performed after preparing the substrate 110 having the main surface 151 bonded with the thermoelectric element 300.

Next, as illustrated in 3c of FIG. 3, the substrate 110 is disposed on the substrate 210 placed so that the main surface 252 is in contact with the placement surface 221 of a fixture 220 so that the main surface 151 faces the substrate 210, and the thermoelectric elements 300 and the bonding material 212 are aligned. Next, a step of disposing the substrate 110 having the main surface 151 bonded with the thermoelectric element 300 on the substrate 210 will be described in detail.

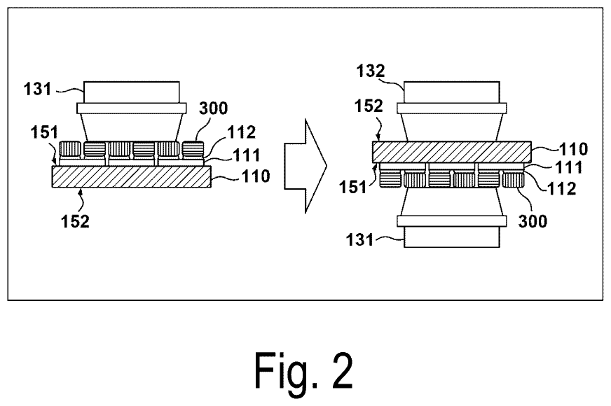

In order to dispose the substrate 110 bonded with the thermoelectric element 300, on the substrate 210, the substrate 110 is first lifted from a side of the main surface 151 using a support 131 as illustrated on the left side of FIG. 2. The support 131 can be, for example, a support for surface-mounting such as a flip-chip bonder. The support 131 suctions a region including a portion of the substrate 110 bonded with the thermoelectric element 300 so as to adsorb to the substrate 110 bonded with the thermoelectric element 300. Then, the substrate 110 is lifted by moving the support 131 upward. Cream solder or the like is not dispensed to the surface of the thermoelectric element 300 to be bonded to the bonding material 212. A metal layer (for example, the above-described solder receiving layer) or the like for bonding to the bonding material 212 is arranged on the surface of the thermoelectric element 300 to be bonded to the bonding material 212 to protect the surface, and thus, the influence caused by the contact of the support 131 on the subsequent steps is small. Therefore, the substrate 110 having the main surface 151 bonded with the thermoelectric element 300 can be lifted if the substrate 110 is suctioned from the side of the main surface 151 by the support 131 and the substrate 110 adsorbs to the support 131.

After the substrate 110 is lifted using the support 131, the lifted substrate 110 is supported from the side of the main surface 152 using a support 132 as illustrated on the right side of FIG. 2. The support 132 can be, for example, a support for surface-mounting such as a flip-chip bonder, similarly to the support 131. At this time, the substrate 110 supported by the support 131 may be turned over and then the substrate 110 may be supported by the support 132. Alternatively, for example, the substrate 110 may be turned over in a state where the substrate 110 is supported by the support 131 and the support 132. For example, the substrate 110 may be turned over after the support 131 is removed in a state where the substrate 110 is supported by the support 132. The support 132 can support the substrate 110 by, for example, adsorbing to the main surface 152 of the substrate 110.

The substrate lifted by the support 131 is supported from the side of the main surface 152 by using the support 132. Next, after the support 131 is removed from the substrate 110 in a state in which the substrate 110 is supported by the support 132, as illustrated in 3c of FIG. 3, the thermoelectric elements 300 and the bonding material 212 disposed on the main surface 251 of the substrate 210 are aligned with each other. Here, a case will be considered in which the substrate 210 provided with the bonding material 212 on the main surface 251 is turned over and is aligned on the substrate 110 bonded with the thermoelectric element 300. In such a case, in order to turn over the substrate 210, a portion of the main surface 251 of the substrate 210 dispensed with cream solder or the like as the bonding material 212 cannot be suctioned and lifted. This is because the cream solder is suctioned. If a space for adsorption is provided in the substrate 210, the use efficiency of the substrate 210 decreases. On the other hand, in the present embodiment, as described above, the substrate 110 bonded with the thermoelectric element 300 can be lifted from the side of the main surface 151 provided with the thermoelectric element 300. Therefore, in the substrate 110 and the substrate 210, a space unusable as the thermoelectric module 500 is reduced. That is, the manufacturing efficiency of the thermoelectric module 500 can be improved.

In the configuration illustrated in FIG. 2, a configuration is illustrated in which the substrate 110 is directly transferred between the support 131 and the support 132. However, the step of disposing the substrate 110 bonded with the thermoelectric element 300, on the substrate 210 is not limited thereto. For example, the singulated substrate 110 is stored in a tray or a tape reel with the main surface 152 of the substrate 110 facing upward using a taping device, a sorter, or the like, and is supplied to a device including the support 132 such as a surface-mounting machine. Then, the support 132 may lift the substrate 110 stored in the tray or the tape reel from the side of the main surface 152.

After the thermoelectric element 300 bonded to the substrate 110 and the bonding material 212 disposed on the substrate 210 are aligned, the thermoelectric element 300 and the bonding material 212 are brought into contact with each other. Next, the substrate 110 and the substrate 210 are bonded to each other via the thermoelectric elements 300 and the bonding materials 112 and 212 as illustrated in 3d of FIG. 3 by a heating process using a reflow oven or the like.

As illustrated in 3d of FIG. 3, a plurality of the substrates 110 having the main surface 151 bonded with the thermoelectric elements 300 may be prepared, and may be aligned with respective predetermined positions on the substrate 210 and bonded thereto. In such a case, after a step of bonding the substrates 110 and the substrate 210 via the thermoelectric element 300, a step of singulating the plurality of the substrates 110 and the substrate 210 bonded to each other into individual substrates 110 may be further included. Thereby, the thermoelectric module 500 as illustrated in FIG. 4 is formed. The plurality of the substrates 110 and the substrate 210 bonded to each other may be singulated using dicing or the like as in the step illustrated in 1e of FIG. 1. Before being singulated, a protective member for protecting the thermoelectric elements 300 in the step of singulating may be injected between the substrate 110 and the substrate 210, for example, from between each of the plurality of substrates 110, and the space between the substrate 110 and the substrate 210 may be at least partially filled with the protective member. For example, one substrate 110 may be bonded to one substrate 210 via the thermoelectric element 300 to function as one thermoelectric module 500, or a plurality of the substrates 110 may be bonded to one substrate 210 via the thermoelectric element 300 to function as one thermoelectric module 500.

As described above, when the substrate 110 and the substrate 210 are bonded to each other via the thermoelectric element 300, the substrate 110 bonded with the thermoelectric element 300 is turned over and moved onto the substrate 210. Thus, the thermoelectric module 500 can be manufactured more efficiently than a case where the substrate 210 is turned over and moved onto the substrate 110 bonded with the thermoelectric element 300.

Each of the above-described steps is described as a step performed when assuming a surface-mounting. Therefore, the thermoelectric element 300 is disposed on the substrate 110 with high density and high accuracy, and, as a result, the area ratio of the thermoelectric elements 300 occupied in the thermoelectric module 500 formed may be increased. The performance of the thermoelectric module 500 may be proportional to an area in which the thermoelectric element 300 is disposed in the thermoelectric module 500 when the performance of the thermoelectric element 300 is constant. Therefore, if the manufacturing process according to the present embodiment is employed, it is possible to efficiently provide the thermoelectric module 500 having a high performance.

In the above description, in an example, solder (cream solder) is employed as the bonding materials 112 and 212. However, the material of the bonding materials 112 and 212 is not limited to solder. Other materials may be employed for the bonding materials 112 and 212 as long as electrical and mechanical bonding between the electrode patterns 111 and 211 and the thermoelectric element 300 is possible. For example, an electrically conductive adhesive such as silver paste or an anisotropic conductive film (ACF) may be employed for the bonding materials 112 and 212.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

What is claimed is:

1. A method for manufacturing a thermoelectric module comprising:
preparing a first substrate including a first main surface and a second main surface and having a thermoelectric element bonded to the first main surface;
dispensing a bonding material to a predetermined position on a third main surface of a second substrate including the third main surface and a fourth main surface;
aligning the thermoelectric element and the bonding material with each other by disposing the first substrate on the second substrate placed with the fourth main surface in contact with a placement surface of a fixture such that the first main surface faces the second substrate; and
bonding the first substrate and the second substrate via the thermoelectric element and the bonding material by bringing the thermoelectric element and the bonding material into contact with each other.

2. The method for manufacturing a thermoelectric module according to claim 1, wherein
the aligning includes:
lifting the first substrate from a side of the first main surface by using a first support; and
supporting the first substrate lifted from a side of the second main surface by using a second support, removing the first support from the first substrate, and then aligning the thermoelectric element and the bonding material with each other.

3. The method for manufacturing a thermoelectric module according to claim 2, wherein the first support lifts the first substrate by suctioning a region including a portion of the first substrate to which the thermoelectric element is bonded.

4. The method for manufacturing a thermoelectric module according to claim 1, wherein
in the preparing, a plurality of the first substrates are prepared,
in the bonding, the plurality of the first substrates are bonded to respective predetermined positions on the second substrate, and
the method further comprises singulating the plurality of the first substrates and the second substrate bonded to each other for each of the first substrates after the bonding.
